(19) United States
(12) Patent Application Publication
(10) Pub. No.: US 2024/0417534 A1
(43) Pub. Date: Dec. 19, 2024

(54) INJECTABLE THERMALLY CONDUCTIVE CURABLE COMPOSITION

(71) Applicant: SIKA TECHNOLOGY AG, Baar (CH)

(72) Inventors: David HOFSTETTER, Winterthur (CH); Andrea BATTISTI, Zürich (CH); Marcel OERTLI, Winterthur (CH); Christian EYHOLZER, Watt (CH); Fabien CHOFFAT, Rüttenen (CH)

(73) Assignee: SIKA TECHNOLOGY AG, Baar (CH)

(21) Appl. No.: 18/715,938

(22) PCT Filed: Dec. 16, 2022
(86) PCT No.: PCT/EP2022/086503

§ 371 Date: Jun. 3, 2024

(30) Foreign Application Priority Data
Dec. 21, 2021 (EP) 21216372.9

(51) Int. Cl. C08K 3/22; C08K 5/521; H01M 10/653; H05K 7/20

(52) U.S. Cl. CPC C08K 3/22; C08K 5/521; C08K 2003/2227; C08K 2201/001; H01M 10/653; H05K 7/2039

(57) ABSTRACT

A two-component moisture-curable composition, especially suitable as thermally conductive gap filler, in particular with flame-retardant properties. It is thus highly suitable for use in e-mobility battery bonding or electronic equipment.

### TECHNICAL FIELD

The invention relates to curable compositions based on polyurethane polymers and their use as injectable gap fillers.

### STATE OF THE ART

Polyurethane compositions which crosslink and cure via the reaction of isocyanate groups with hydroxyl or amino groups, the latter often produced in situ by hydrolysis of parts of the isocyanate groups by moisture or water, are widely used as elastic adhesives, sealants, potting resins, or coatings in the construction and manufacturing industry, for example for bonding of components in assembly, for filling joints, as floor coating or as roof seal.

Owing to their good adhesion properties and elastic toughness, they can gently damp and buffer forces acting on the substrates, triggered for instance by vibrations or variations in temperature while maintaining an excellent adhesive bond to the substrates. This makes them versatile and useful materials for many sealing, bonding, and potting applications. Such polyurethane polymers can also be endcapped by organofunctional alkoxysilanes, which leads to a different moisture-initiated curing mechanism involving hydrolysis and condensation of the alkoxysilane groups, but the mechanical properties of the polymer backbone remain the same.

With the increasing use of batteries and electronic equipment nowadays, the demand for suitable gap fillers, adhesives, and sealants in contact with these electronic elements or devices has risen significantly. Especially in electric automobile assembly, large batteries and a multitude of electronic parts require ever increasing amounts of such gap fillers, sealants and adhesives that cover, seal, or bond electronics and batteries directly, or fill gaps within them. A particular requirement for these gap filler, adhesive, and selant materials in electric and electronic applications is a high heat conductivity, since batteries and electronics generate significant amounts of heat while operating which must be dissipated efficiently to prevent detrimental heat accumulation on the batteries and electronic parts. This aspect has proven to be a severe problem for traditionally used curable compositions, for example polyurethanes based on isocyanate-functional polymers and other polymeric cured materials. All commonly used such polymer-based compositions naturally possess a poor heat conductivity and rather act as thermal insulators than as efficient heat conductors. Common curable polymeric compositions thus are not very suitable for applications requiring high heat dissipation properties.

There have been many attempts to formulate curable compositions with high heat conductivity. The current state of the art most commonly uses silicone-based compositions containing special heat-conductive fillers. Silicones generally have a high heat stability, which is beneficial, but in order to achieve the required heat conductive properties, special fillers are required. Such specially formulated silicones compositions are curable elastomers and show adequate thermal conductivity. However, silicone-based compositions are notoriously difficult to paint or coat and this is a critical problem in the rather young electric automobile industry. Additionally, silicones are especially problematic for electrodeposition coating (“e-coat” or cathode-dipping) processes, which are a common and often indispensable process step in automotive manufacturing, since their formulation constituents tend to migrate and form depositions on metal surfaces, leading to insufficient e-coating results. Many automotive manufacturers thus strictly avoid silicones in their plants to prevent interference with their e-coat processes.

Other proposed curable compositions, such as polyurethanes based on isocyanate-functional polymers, do not interfere with the e-coat process, and they have been successfully implemented recently in heat dissipation applications as just described, and their heat stability is more than sufficient to replace silicones. For example, WO 2021/115810 describes a thermally conductive two-component polyurethane adhesive including surface-treated fillers that can react with isocyanate-groups. WO 2020/176437, as another example, describes a two-part polyurethane thermal interface material, preferably including special aliphatic isocyanate-functional components. Publication WO 2021/158336 is a further example that discloses a thermally conductive composition based on known isocyanate-functional polymers.

Also described were thermally conductive compositions based on silylated polyurethane polymers, where the reactive end groups of the polymers consist of moisture-curable alkoxysilane groups. For example, WO 2018/015552 discloses a thermally conductive two-component composition based on isocyanate-functional polyurethane prepolymers that are subsequently endcapped by isocyanate-reactive silanes. Another example, WO 2020/165288, discloses thermally conductive two-component compositions based on silylated polyurethane polymers obtained by the endcapping of polyethers with isocyanatosilanes. The isocyanate-functional polyurethane polymers disclosed in these publications are produced by conventional processes, for example by reacting diisocyantes with diols using a molar ratio of NCO/OH of about 2.1/1.

However, similar to silicones, in order to produce high thermal conductivity in otherwise naturally rather thermally insulating polyurethane compositions, high levels of heat conducting fillers, as described above and in the prior art, are necessary. For example, to achieve desired heat conductivity levels, such as 2 W/mK according to ASTM D5470, or higher, the required amounts of these fillers within the composition commonly reaches at least 70% by weight of the total composition or even more. This requirement, however, leads to several drawbacks in polyurethane-based compositions. First of all, such high filler amounts normally require careful drying of these fillers in order to ensure a sufficient storage stability in compositions where the moisture-reactive isocyanate-functional or alkoxysilane-functional polymers are stored together. Furthermore, such high filler levels normally have a severe impact on the composition's viscosity and lead to significant thickening of the composition.

For adhesives, this is often not a critical issue, but for gap fillers that are injected into gaps of electric or electronic devices and that need to freely flow and fill the cavities for an optimal thermal dissipation performance, this is a major drawback. Dispersing agents or dispersants can be used to reduce viscosity and to improve flowability, but their use is limited and undesired due to cost, formulation stability, and safety issues.

Hence, there still is a demand for a curable composition that is suitable as low viscosity, injectable gap filler for battery and electronics assembly and that possesses high thermal conductivity but at the same time does not interfere with coating or painting processes, in particular e-coat processes. Furthermore, the compositions should be storage stable without the requirement of drying its fillers and ideally is formulated using commonly available raw materials and without the need to incorporate dispersing agents.

### SUMMARY OF THE INVENTION

It is therefore an object of the present invention to provide a curable composition based on organic polymers containing isocyanate groups that can be formulated with readily available raw materials and is highly storage stable and exhibits high thermal conductivity, in particular of at least 2 W/mK, preferably at least 3 W/mK according to ASTM D5470, and is suitable as injectable gap-filler, sealant, or adhesive for batteries and electronic equipment.

The present invention achieves these objects with the features of independent claim 1.

A two-component moisture-curable composition, comprising in a first component between 50 to 99 parts per volume, based on the total two-component composition, of at least one filler, and between 10 and 30 parts by volume, based on the total two-component composition, of at least one plasticizer, and in a second component between 0.5 and 50 parts per volume, based on the total two-component composition, of at least one polymer containing isocyanate groups or alkoxysilane groups, wherein the volume ratio of the first component to the second component is between 1:1 and 200:1 and said filler is selected from the list consisting of aluminium oxide, aluminium hydroxide, boron nitride, aluminium nitride, magnesium oxide, magnesium hydroxide, zinc oxide, and any mixture of these fillers, said polymer containing isocyanate groups or alkoxysilane groups is obtained from the reaction of at least one monomeric diisocyanate with at least one polyether polyol in an NCO/OH ratio of at least 3/1, and subsequent removal of a majority of the residual monomeric diisocyanates by means of a suitable separation method, and optionally subsequent endcapping of the isocyanate groups on the obtained isocyanate-functional polymer by reaction with an organoalkoxysilane that contains an amino group, a hydroxy group, or a mercapto group, surprisingly enables the formulation of a storage-stable, injectable curable material with high thermal conductivity that can be used together with e-coat processes and does not have the disadvantages of silicone-based products but can be formulated with readily available raw materials and without the need to dry the filler or use dispersing agents.

Further aspects of the invention are the subject of further independent claims. Particularly preferred embodiments of the invention are the subject of the dependent claims.

### Ways of Executing the Invention

The present invention relates in a first aspect to a two-component moisture-curable composition, comprising
in a first component A
   between 50 to 99 parts per volume, based on the total two-component composition, of at least one filler F;
   between 10 and 30 parts by volume, based on the total two-component composition, of at least one plasticizer PL;
   optionally between 0.1 and 2 parts per volume, based on the total two-component composition, of water; and
in a second component B
   between 0.5 and 50 parts per volume, based on the total two-component composition, of at least one polymer P containing isocyanate groups or alkoxysilane groups;
   optionally additives selected from dried fillers, pigments, stabilizers, and plasticizers;
and optionally up to 1 part per volume, based on the total two-component composition, of at least one catalyst for the curing of isocyanate-functional polymers in either one or both of component A and component B;
wherein the volume ratio of component A to component B is between 1:1 and 200:1 and components A and B are stored in separated containers and mixed before or during application of the moisture-curable composition; characterized in that
   said filler F is selected from the list consisting of aluminium oxide, aluminium hydroxide, boron nitride, aluminium nitride, magnesium oxide, magnesium hydroxide, zinc oxide, and any mixture of these fillers; and
   said polymer P containing isocyanate groups or alkoxysilane groups is obtained from the reaction of at least one monomeric diisocyanate with at least one polyether polyol in an NCO/OH ratio of at least 3/1, and subsequent removal of a majority of the residual monomeric diisocyanates by means of a suitable separation method, and optionally subsequent endcapping of the isocyanate groups on the obtained isocyanate-functional polymer by reaction with an organoalkoxysilane that contains an amino group, a hydroxy group, or a mercapto group.

In the present document, “organofunctional compound” refers to a compound that contains a functional group that is bound via a carbon atom. For example, “aminofunctional compound” is a compound having an aminoalkyl group.

The term “reactive silane group” refers to a silyl group that is bonded to an organic radical and has one to three, especially two or three, hydrolyzable substituents or hydroxyl groups on the silicon atom. Particularly useful hydrolyzable substituents are alkoxy groups. These silane groups are also referred to as “alkoxysilane groups”. Reactive silane groups may also be in partly or fully hydrolyzed form, for example as silanols.

“Hydroxysilane”, “isocyanatosilane”, “aminosilane” and “mercaptosilane” refer respectively to organoalkoxysilanes having one or more hydroxyl, isocyanate, amino or mercapto groups on the organic radical in addition to the silane group.

“Primary amino group” refers to an NH₂ group that is bonded to an organic radical, and “secondary amino group” refers to an NH group that is bonded to two organic radicals which may also together be part of a ring, and “tertiary amino group” refers to an N group that is bonded to three organic radicals, two or three of which together may also be part of one or more rings. Accordingly, “primary aminosilanes” are aminosilanes comprising a primary amino group and “secondary aminosilanes” are aminosilanes comprising a secondary amino group. The latter also encompasses compounds having both a primary and a secondary amino group.

“Polyoxyalkylene radical” refers to a linear or branched hydrocarbyl radical which contains ether groups and contains more than two repeat units of the (O-R) type in succession, where R is a linear or branched alkylene radical, as for example from the polyaddition of ethylene oxide or 1,2-propylene oxide onto starter molecules having two active hydrogen atoms.

Substance names beginning with “poly”, such as polyol or polyisocyanate, refer to substances containing, in a formal sense, two or more of the functional groups that occur in their name per molecule.

The term “organic polymer” encompasses a collective of macromolecules that are chemically homogeneous but differ in relation to degree of polymerization, molar mass and chain length, which has been prepared by a poly reaction (polymerization, polyaddition, polycondensation) and has a majority of carbon atoms in the polymer backbone, and reaction products of such a collective of macromolecules. Polymers having a polyorganosiloxane backbone (commonly referred to as “silicones”) are not organic polymers in the context of the present document.

“Molecular weight” is understood in the present document to mean the molar mass (in grams per mole) of a molecule or part of a molecule, also referred to as “radical”. The term “radical” is used in this document in a formal sense, meaning a molecular rest bound to an atom by a covalent bond, while the bond is formally “cut” to describe the molecular rest attached to it. Molecular weight of polymers is understood as the average molecular weight of their chain length distribution. “Average molecular weight” refers to the number-average molecular weight (Mₙ) of a polydisperse mixture of oligomeric or polymeric molecules or molecule residues. It is determined by means of gel permeation chromatography (GPC) against polystyrene as standard, especially with tetrahydrofuran as mobile phase, refractive index detector and evaluation from 200 g/mol.

“Storage-stable” or “storable” refers to a substance or composition when it can be stored at room temperature in a suitable container over a prolonged period, typically at least 3 months up to 6 months or more, without any change in its application or use properties, especially in the viscosity and crosslinking rate, to a degree of relevance for the use thereof as a result of the storage.

Thermal conductivity λ is defined as ability of material to transmit heat and it is measured in watts per square metre (W/m²) of surface area for a temperature gradient of 1 K per unit thickness of 1 m. Thermal conductivity of materials disclosed in this document are measured according to ASTM D5470-06.

All industrial standards and norms cited in this document refer to the respective edition in force on the time of filing of the first application of this invention, if not otherwise defined.

“Monomeric diisocyanate” refers to an organic compound having two isocyanate groups separated by a divalent hydrocarbyl radical having 4 to 15 carbon atoms.

“NCO content” refers to the content of isocyanate groups in % by weight.

An “aromatic” isocyanate group refers to one bonded directly to an aromatic carbon atom. Isocyanates having exclusively aromatic isocyanate groups are correspondingly referred to as “aromatic isocyanates”.

An “aliphatic” isocyanate group refers to one bonded directly to an aliphatic or cycloaliphatic carbon atom. Isocyanates having exclusively aliphatic isocyanate groups are correspondingly referred to as “aliphatic isocyanates”.

A “polyetherurethane polymer” refers to a polymer having ether groups as repeat units and additionally containing urethane groups.

A “primary amino group” refers to an amino group which is bonded to a single organic radical and bears two hydrogen atoms; a “secondary amino group” refers to an amino group which is bonded to two organic radicals which may also together be part of a ring and bears one hydrogen atom; and a “tertiary amino group” refers to an amino group which is bonded to three organic radicals, two or three of which may also be part of one or more rings, and does not bear any hydrogen atom.

“Room temperature” refers to a temperature of 23° C.

A dotted line in the formulae in each case represents the bond between a substituent and the corresponding molecular radical.

Percentages by weight (% by weight), abbreviated to wt %, refer to proportions by mass of a constituent of a composition or a molecule, based on the overall composition or the overall molecule, unless stated otherwise. The terms “weight” and “mass” are used interchangeably in this document and refer to the mass as a property of a physical body and commonly measured in kilograms (kg).

The term “parts per volume” defines the volumetric amount, for example expressed in litres, of a specific ingredient added to a composition and is always understood in relation to the volumetric amount of at least one other ingredient added to the same composition. Parts per volume are not percentages and do not necessarily add up to 100, but they define the amount ratio of different ingredients to be added to a composition relative to each other.

For compositions of the present invention, it was found that the relative amounts of the key ingredients are more meaningful when defined by volume instead of by weight, as some of the ingredients, in particular filler F, may have large variations in density between different embodiments.

The term “volume” is understood within this document as the calculated value obtained from dividing the weight of a substance added to or contained in a composition by the substance's density at 20° C. and 1 bar atmospheric pressure. However, volumes of liquids may for example also be measured by calibrated flasks, while volumes of particles of unknown density may for example be calculated by first determining the particle density using a pycnometer and the Archimedes principle.

The two-component moisture-curable composition comprises in the first component A
between 50 to 99 parts per volume, based on the total two-component composition, of at least one filler F;
between 10 and 30 parts by volume, based on the total two-component composition, of at least one plasticizer PL;
optionally between 0.1 and 2 parts per volume, based on the total two-component composition, of water.

The composition according to the present invention comprises in first component A between 50 to 99 parts per volume, preferably between 60 and 90 parts by volume, in particular between 70 and 80 parts by volume, based on the total two-component composition, of at least one filler F.

Said filler F is selected from the list consisting of aluminium oxide (Al₂O₃), aluminium hydroxide (ATH; Al(OH)₃), boron nitride (BN), aluminium nitride (AlN), magnesium oxide (MgO), magnesium hydroxide (Mg(OH)₂), zinc oxide (ZnO), and any mixture of these fillers.

Fillers F selected from this list enable the intended high thermal conductivity of the composition and they are commonly available and comparably inexpensive.

Those fillers can be surface-treated, in particular hydrophobized, for example with fatty acid stearate coatings such as stearate, or silane coatings, such as octyl silane. Fillers treated in this manner may have the advantage of better miscibility with polymers P, for example.

Due to the two-component setup of the composition according to the present invention, wherein the moisture-reactive polymers P and fillers F are stored separately, it is not necessary to expensively dry fillers F when they naturally contain significant amounts of adsorbed water. This is a significant cost advantage and ensures high storage stability of the compositions.

It is preferred in some embodiments to use more than one type of filler F, for example aluminium oxide and aluminium hydroxide. By mixing different fillers, thermal conductivity properties may be maximized and/or other properties, such as dielectricity, density, mechanical properties, or flame-retardant properties may be improved.

In the same or different preferred embodiments, a filler F or a mixture of fillers F is used that combines different particle sizes. For example, it is advantageous to use a bimodal or multimodal particle size range for the employed fillers. When at least one filler ensemble with relatively large particles and at least another one with relatively small particles are used together, a higher density of close packing of spheres may be achieved, which is beneficial for heat conductivity and compounding when using small amounts of polymer P and high amounts of filler F.

In preferred embodiments of the two-component moisture-curable composition according to present invention, filler F comprises or consists of aluminium oxide and aluminium hydroxide (ATH). This combination has the advantage that it shows especially good thermal conductivity and at the same time excellent flame-retardant properties. This makes it especially suitable for battery assemblies. Even more advantageous in this regard is the combination of fillers F comprising or consisting of ATH with flame-retardant plasiticizers PL such as trialkyl or triaryl phosphates discussed further below.

Especially good flame retardant properties with still sufficient thermal conductivity are achieved by using prevalently aluminium hydroxide (ATH) as filler F.

In preferred embodiments of the two-component moisture-curable composition according to present invention, filler F comprises or consists of a multimodal aluminium hydroxide having a hydrophobic coating. This type of filler F combines the advantages of excellent flame retardant properties and excellent thermal conductivity due to the possible high amounts that can be incorporated in the composition.

In preferred embodiments of the two-component moisture-curable composition according to present invention, said filler F comprises or consists of aluminium hydroxide and optionally aluminium oxide, optionally furthermore comprising boron nitride and/or magnesium oxide.

For example, thermal conductivity can be increased by adding a more thermally conductive filler F. For example, the thermal conductivity of suitable fillers F rises from ATH<Al₂O₃<MgO<BN. The choice of suitable fillers F or their mixture is however preferably limited to highly dielectric fillers, especially in electric or electronic applications where dielectric properties are a safety requirement.

Filler F is in all embodiments advantageously added in powder form or at least finely particulate, in order to ensure homogeneous compounding when used in high amounts.

In preferred embodiments of the two-component moisture-curable composition according to present invention, the composition comprises between 85.0 and 92.0% by weight, based on the total two-component composition, of said filler F.

The two-component moisture-curable composition according to present invention comprises in the first component A between 10 and 30 parts by volume, preferably between 15 and 25 parts by volume, based on the total two-component composition, of at least one plasticizer PL.

Plasticizer PL is a required constituent in the first component A and enables a homogeneous dispersion of filler F and proper miscibility of both components A and B. Higher amounts of plasticizer PL within the claimed range are useful when comparably high amounts of filler F are to be included in the formulation. Furthermore, plasticizer PL in higher amounts may advantageously decrease the viscosity of the total composition, which is especially beneficial for gap filler applications.

Plasticizer PL may be any of the plasticizers commonly used in compositions based on isocyanate-functional polymers. These include, for example, carboxylic esters such as phthalates, especially dioctyl phthalate, bis(2-ethylhexyl) phthalate, bis(3-propylheptyl) phthalate, diisononyl phthalate or diisodecyl phthalate, diesters of ortho-cyclohexane-dicarboxylic acid, especially diisononyl 1,2-cyclohexanedicarboxylate, adipates, especially dioctyl adipate, bis(2-ethylhexyl) adipate, azelates, especially bis(2-ethylhexyl) azelate, sebacates, especially bis(2-ethylhexyl) sebacate or diisononyl sebacate, glycol ethers, glycol esters, organic phosphoric or sulfonic esters, sulfonamides, polybutenes, or fatty acid methyl or ethyl esters derived from natural fats or oils, also called “biodiesel”.

Furthermore, suitable are polymeric plasticizers. These have the advantage of lower migration tendency into surrounding areas and lower contribution to VOC levels.

The term “polymeric plasticizer” herein means a polymeric additive that is liquid at room temperature and contains no hydrolyzable silane groups. In contrast to traditional plasticizers, such as phthalates, the polymeric plasticizers generally have a higher molecular weight.

Preferably, the polymeric plasticizer has an average molecular weight Mₙ of 500 to 12′000 g/mol, in particular 1′000 to 10′000 g/mol, more preferably 2′500 to 5′000 g/mol.

Suitable polymeric plasticizers include polyols, such as those suitable for the production of polymers P mentioned there, as long as they are liquid at room temperature, and polyols where the OH-groups have been reacted to chemically inert functional groups. Preferred polyols suitable as polymeric plasticizers include polyether polyols, polyester polyols, polyhydrocarbon polyols, polybutadiene polyols, and poly(meth)acrylate polyols. Particularly preferred are polyether polyols, especially those with an average molecular weight of Mₙ of 500 to 12′000 g/mol, especially 1′000 to 10′000 g/mol, more preferably 2′500 to 5′000 g/mol.

Most preferred plasticizers PL for the moisture-curable composition according to the present invention comprise or consist of a trialkyl and/or triaryl phosphate, for example triethyl phosphate, tricresyl phosphate, triphenyl phosphate, diphenyl cresyl phosphate, isodecyl diphenyl phosphate, tris(1,3-dichloro-2-propyl) phosphate, tris(2-chloroethyl) phosphate, tris(2-ethylhexyl) phosphate, tris(chloroisopropyl) phosphate, tris(chloropropyl) phosphate, isopropylated triphenyl phosphate, mono-, bis- or tris(isopropylphenyl) phosphates. Preferred trialkyl and/or triaryl phosphate plasticizers PL are tris-(2-ethylhexyl)-phosphate (sold under the trade name Disflamoll® TOF by Lanxess), cresyl diphenyl phosphate, tricresyl phosphate, and triphenyl phosphate (all sold under the trade name range Disflamoll® by Lanxess).

Trialkyl and/or triaryl phosphate plasticizers have the advantage that they improve the flame-retardant properties of the composition. Most preferred plasticizer is tris-(2-ethylhexyl)-phosphate.

In preferred embodiments of the two-component moisture-curable composition according to the present invention, the composition comprises between 7.0 and 12.0% by weight, based on the total two-component composition, of said plasticizer PL.

The two-component moisture-curable composition according to present invention optionally comprises in the first component A between 0.1 and 2 parts per volume, based on the total two-component composition, of water.

The addition of water to the first component A accelerates the curing of the mixed two-component composition without the need to rely on moisture from air. This is especially advantageous in cases where a fast curing of the composition is required, or in cases where diffusion of moisture into the composition is hindered, such as narrow gaps with only a small portion of the applied composition exposed to air. However, especially in cases where non-dried fillers F are used, the naturally present amount of adsorbed water in those fillers is often sufficient for curing of the low amounts of polymer P used. Addition of water is thus preferred in cases where an especially fast curing is intended or in cases where isocyanates with comparably low reactivity, especially aliphatic isocyanates such as IPDI, are used.

The two-component moisture-curable composition according to present invention optionally comprises up to 1 part per volume, based on the total two-component composition, of at least one catalyst for the curing of isocyanate-functional polymers or alkoxysilane-functional polymers in either one or both of component A and component B.

In some embodiments, said catalyst is contained in component B. These embodiments exhibit especially homogeneous and fast curing behavior, as the reactive isocyanate groups of polymer P and the catalyst are in advantageous proximity to each other already during or immediately after mixing of components A and B.

In other embodiments, said catalyst is only contained in component A. These embodiments exhibit especially good storage stability of component B, particularly in cases where traces of water are present in component B.

The addition of catalyst, similar to water as discussed above, may be advantageous in some embodiments to ensure a sufficient curing rate given the fact that generally low amounts of reactive polymers P are used. However, a catalyst is not in every case necessary. In particular when using a highly reactive polymer P, for example one based on aromatic isocyanates such as MDI, a catalyst may be omitted. Also, the amount of catalyst, when used, may be tailored to the intended curing rate of a specific embodiment of the inventive two-component composition, as higher amounts of catalyst generally lead to faster curing rates.

Suitable catalysts for embodiments where isocyanate-functional polymers P are used are all commonly used curing catalysts for polyurethane compositions based on isocyanate-functional polymers, especially metal compounds and/or basic nitrogen or phosphorus compounds.

For embodiments where alkoxysilane-functional polymers P are used, generally the same catalysts may be used as in the case of isocyanate-functional polymers P. In these cases, however, it is preferred to include at least one aminosilane and/or at least one organic compound containing a tertiary amino group, an amidine group, or a guandine group as catalyst or as co-catalyst together with a metal-based catalyst.

Suitable metal compounds as catalysts in all embodiments are especially compounds of tin, titanium, zirconium, aluminum or zinc, especially diorganotin(IV) compounds such as, in particular, dibutyltin(IV) diacetate, dibutyltin(IV) dilaurate, dibutyltin(IV) dineodecanoate or dibutyltin(IV) bis(acetylacetonate) and dioctyltin(IV) dilaurate, and also titanium(IV) or zirconium(IV) or aluminum(III) or zinc(II) complexes, especially with alkoxy, carboxylate, 1,3-diketonate, 1,3-ketoesterate or 1,3-ketoamidate ligands.

Suitable basic nitrogen or phosphorus compounds are especially imidazoles, pyridines, phosphazene bases, secondary or tertiary amines, hexahydrotriazines, biguanides, guanidines, or amidines.

Nitrogen-containing compounds suitable as catalysts are in particular amines, especially N-ethyl-diisopropylamine, N,N,N′,N′-tetramethylalkylenediamines, 1,4-diazabicyclo[2.2.2]octane; amidines such as especially 1,8-diazabicyclo[5.4.0]undec-7-ene (DBU), 1,5-diazabicyclo[4.3.0]non-5-ene (DBN), 6-dibutylamino1,8-diazabicyclo-[5.4.0]undec-7-ene; and guanidines such as especially tetramethylguanidine, 2-guanidino-benzimidazole, acetylacetone-guanidine, 3-di-o-tolyl-guanidine, 2-tert-butyl-1,1,3,3-tetramethyl guanidine.

Preferred catalysts in all embodiments are especially organotin(IV) compounds, such as especially dibutyltin diacetate, dibutyltin dilaurate, dibutyltin dichloride, dibutyltin diacetylacetonate, dimethyltin dilaurate, dioctyltin diacetate, dioctyltin dilaurate or dioctyltin diacetylacetonate, complexes of bismuth(III) or zirconium(IV), especially with ligands selected from alkoxides, carboxylates, 1,3-diketonates, oxinate, 1,3-ketoesterates and 1,3-ketoamidates, or compounds containing tertiary amino groups, such as especially 2,2′-dimorpholinodiethyl ether (DMDEE).

Also, especially suitable are combinations of different catalysts. Component A may comprise further additives in comparably small amounts. This mainly includes common additives in polyurethane formulation, such as the optional additives for component B defined further below.

However, in preferred embodiments, component A consists of the mandatory and optionally the optional ingredients listed further above.

The two-component moisture-curable composition comprises in the second component B
between 0.5 and 50 parts per volume, based on the total two-component composition, of at least one polymer P containing isocyanate groups;
optionally additives selected from dried fillers, pigments, stabilizers, alkoxysilanes, catalysts, and plasticizers.

The composition according to the present invention comprises in second component B between 0.5 and 50 parts per volume, preferably between 0.75 and 25 parts per volume, in particular between 1 and 10 parts per volume, most preferably between 1.5 and 5 parts per volume, based on the total two-component composition, of at least one polymer P containing isocyanate groups or alkoxysilane groups.

Polymer P containing isocyanate groups may also be referred to as (isocyanate-functional or alkoxysilane-functional) polyurethane prepolymer.

Polymer P containing isocyanate groups or alkoxysilane groups is preferably liquid at room temperature.

Some embodiments of the present invention employ polymers P containing isocyanate groups. These embodiments generally exhibit an especially low viscosity and are especially suitable as free-flowing gap fillers, and the corresponding polymers P are especially easily available.

Other embodiments of the present invention employ polymers P containing alkoxysilane groups. These embodiments initially use the same polymers P as embodiments using isocyanate-functional polymers P, with the difference however that an additional process step is performed, wherein the isocyanate groups of these polymers are reacted with amino-, hydroxy-, or mercapto-functional alkoxysilanes. This leaves the polymer backbone unchanged but introduces different moisture-reactive endgroups, which may be an advantage in storage stability or for cases where reactive isocyanate groups need to be avoided. Additionally, such polymers bring about the advantage of generally better adhesion properties. The introduction of alkoxysilane groups is optional and covers certain embodiments of the invention, but the general aspects of the formulation and the inventive effects thereof remain unchanged compared to embodiments where isocyanate-functional polymers P are used.

The polymer P containing isocyanate groups or alkoxysilane groups preferably has a monomeric diisocyanate content of not more than 0.3% by weight, especially not more than 0.2% by weight. Such a polymer is particularly suitable for the production of formulations such as, in particular, elastic adhesives, sealants and coatings or gap fillers that have a monomeric diisocyanate content of less than 0.1% by weight; these can be safely handled even without special safety precautions and can thus be sold in many countries without hazard labeling. Furthermore, the absence of monomeric diisocyanates in contents above 0.3% by weight within the polymer leads to better curing performance and less bubbling and other undesired effects.

The polymer P containing isocyanate groups or alkoxysilane groups preferably has an average molecular weight Mₙ in the range from 6000 to 20 000 g/mol, which may be determined by means of gel permeation chromatography (GPC) against polystyrene as standard, especially with tetrahydrofuran as mobile phase, refractive index detector and evaluation from 200 g/mol.

In embodiments where a polymer P containing isocyanate groups is used, said polymer P containing isocyanate groups preferably has an NCO content in the range from 0.5% to 10% by weight, preferably 0.6% to 8.4% by weight, especially 0.8% to 7% by weight.

In a preferred embodiment of the invention where a polymer P containing isocyanate groups is used, said polymer P containing isocyanate groups has an average molecular weight Mₙ in the range from 1000 to 4000 g/mol, especially 1200 to 3000 g/mol. The NCO content is preferably in the range from 2.1% to 8.4% by weight, especially 2.8% to 7% by weight. Such a polymer P containing isocyanate groups is particularly suitable for use in elastic coatings for electric or electronic equipment, for example. It is preferably obtained from the reaction of at least one diol having an OH number in the range from 37 to 190 mg KOH/g, especially in the range from 56 to 150 mg KOH/g.

In a further preferred embodiment of the invention where a polymer P containing isocyanate groups is used, said polymer P containing isocyanate groups has an average molecular weight Mₙ in the range from 3500 to 15 000 g/mol, more preferably 4000 to 12 000 g/mol, especially 5000 to 10 000 g/mol. The NCO content is preferably in the range from 0.6% to 3.5% by weight, more preferably 0.7% to 3% by weight, especially 0.8% to 2.5% by weight. Such a polymer P containing isocyanate groups is particularly suitable for use in elastic sealants or adhesives or gap fillers. It is preferably obtained from the reaction of at least one polyol having an average OH functionality in the range from 1.9 to 3 and in OH number in the range from 8 to 56 mg KOH/g, 10 to 42 mg KOH/g.

Suitable monomeric diisocyanates for the production of polymer P in all embodiments are commercial aromatic or aliphatic diisocyanates, especially diphenylmethane 4,4′-diisocyanate, optionally with fractions of diphenylmethane 2,4′- and/or 2,2′-diisocyanate (MDI), tolylene 2,4-diisocyanate or mixtures thereof with tolylene 2,6-diisocyanate (TDI), phenylene 1,4-diisocyanate (PDI), naphthalene 1,5-diisocyanate (NDI), hexane 1,6-diisocyanate (HDI), 2,2(4),4-trimethylhexamethylene 1,6-diisocyanate (TMDI), cyclohexane 1,3- or 1,4-diisocyanate, 1-isocyanato-3,3,5-trimethyl-5-isocyanatomethylcyclohexane (isophorone diisocyanate or IPDI), perhydro-diphenylmethane 2,4′- or 4,4′-diisocyanate (HMDI), 1,3- or 1,4-bis(isocyanatomethyl)cyclohexane, m- or p-xylylene diisocyanate (XDI), m-tetramethylxylylene diisocyanate (TMXDI), or mixtures thereof.

The monomeric diisocyanate is preferably a sterically hindered diisocyanate, especially TDI, TMDI, IPDI or TMXDI. Such diisocyanates afford moisture-curing polyurethane compositions having particularly good storage stability, long open time and high extensibility, but which cure only poorly with a low monomeric diisocyanate content without additional use of blocked amines.

Most preferred among these is IPDI as monomeric diisocyanate. In this way, moisture-curing polyurethane compositions having good storage stability, long open time, high strength and particularly high stability to oxidative or thermal influences are obtained. Moisture-curing polyurethane compositions based thereon and having a low monomeric diisocyanate content, however, cure only very slowly by means of moisture at ambient temperatures, and in such cases it is recommended to add catalysts to component A, such as organotin(IV) compounds in particular, and/or water in order to increase the curing rate.

Further preferably, the monomeric diisocyanate is a sterically unhindered diisocyanate, especially MDI, PDI, HDI or HMDI. Such diisocyanates afford moisture-curing polyurethane compositions having a particularly high curing rate and strength, and they can be used in formulation without added catalyst.

Most preferred among these is diphenylmethane 4,4′-diisocyanate as monomeric diisocyanate. In this way, moisture-curing polyurethane compositions having surprisingly good storage stability, particularly rapid curing and particularly high strength coupled with high elasticity are obtained, even in cases where no additional catalyst is included in component A.

Suitable polyols for polymer P in all embodiments are commercial polyols that are preferably liquid at room temperature.

Preference is given to polyols having an average molecular weight Mₙ in the range from 800 to 15 000 g/mol, more preferably 1000 to 12 000 g/mol, especially 2000 to 8500 g/mol.

The polyol preferably has an average OH functionality in the range from 1.7 to 3.

The polyol is preferably a diol or triol having an OH number in the range from 8 to 185 mg KOH/g, especially in the range from 10 to 120 mg KOH/g.

In one embodiment, preference is given to diols having an OH number in the range from 37 to 185 mg KOH/g, especially in the range from 44 to 120 mg KOH/g. Such a polymer containing isocyanate groups is particularly suitable for use in elastic coatings for sealing of electric or electronic equipment, for example.

In a further embodiment, preference is given to diols or triols having an OH number in the range from 8 to 56 mg KOH/g, especially in the range from 10 to 42 mg KOH/g. Such a polymer containing isocyanate groups is particularly suitable for use in elastic sealants or adhesives or gap fillers.

The polyol used for polymer P in all embodiments is a polyether polyol, and the polymer P containing isocyanate groups or alkoxysilane groups obtained therefrom is thus a polyetherurethane polymer containing isocyanate groups or alkoxysilane groups. Such a polymer enables moisture-curing polyurethane compositions having high extensibility and elasticity.

Repeat units present therein are preferably 1,2-ethyleneoxy, 1,2-propyleneoxy, 1,3-propyleneoxy, 1,2-butyleneoxy or 1,4-butyleneoxy groups. More preferably, repeat units present in the polyether polyol are mainly or exclusively 1,2-propyleneoxy groups. More particularly, based on all repeat units, it has 80% to 100% by weight of 1,2-propyleneoxy groups and 0% to 20% by weight of 1,2-ethyleneoxy groups.

Polyoxyalkylene diols and/or polyoxyalkylene triols are particularly suitable, especially polymerization products of ethylene oxide or 1,2-propylene oxide or 1,2- or 2,3-butylene oxide or oxetane or tetrahydrofuran or mixtures thereof, where these may be polymerized with the aid of a starter molecule having two or more active hydrogen atoms, especially a starter molecule such as water, ammonia or a compound having multiple OH or NH groups, such as, for example, ethane-1,2-diol, propane-1,2- or -1,3-diol, neopentyl glycol, diethylene glycol, triethylene glycol, the isomeric dipropylene glycols or tripropylene glycols, the isomeric butanediols, pentanediols, hexanediols, heptanediols, octanediols, nonanediols, decanediols, undecanediols, cyclohexane-1,3- or -1,4-dimethanol, bisphenol A, hydrogenated bisphenol A, 1,1,1-trimethylolethane, 1,1,1-trimethylolpropane, glycerol or aniline, or mixtures of the abovementioned compounds.

Particular preference is given to polyoxypropylene diols, polyoxypropylene triols, or ethylene oxide-terminated polyoxypropylene diols or triols. These are polyoxyethylene/polyoxypropylene copolyols which are obtained especially by further alkoxylating polyoxypropylene diols or triols with ethylene oxide on conclusion of the polypropoxylation reaction, with the result that they ultimately have primary hydroxyl groups.

Preferred polyether polyols have a level of unsaturation of less than 0.02 meq/g, especially less than 0.01 meq/g.

In one embodiment, preference is given to a trimethylolpropane- or especially glycerol-started, optionally ethylene oxide-terminated, polyoxypropylene triol having an average molecular weight Mₙ in the range from 3500 to 15 000 g/mol, preferably 4000 to 12 000 g/mol, especially 4500 to 8500 g/mol.

In especially preferred embodiments of the two-component moisture-curable composition according to present invention, said polyether polyol is a polyether triol having an average OH functionality in the range from 2.2 to 3, preferably 2.2 to 2.8, especially 2.2 to 2.6, and an OH number in the range from 10 to 42 mg KOH/g, especially 20 to 35 mg KOH/g.

In the same or different especially preferred embodiments of the two-component moisture-curable composition according to present invention, said diisocyanate is diphenylmethane 4,4′-diisocyanate or 1-isocyanato-3,3,5-trimethyl-5-isocyanatomethylcyclohexane.

In all embodiments, the NCO/OH ratio in the reaction between the monomeric diisocyanate and the polyol is preferably in the range from 3/1 to 10/1, more preferably in the range from 3/1 to 8/1, especially in the range from 4/1 to 7/1.

The reaction between the monomeric diisocyanate and the polyol is preferably conducted with exclusion of moisture at a temperature in the range from 20 to 160° C., especially 40 to 140° C., optionally in the presence of suitable catalysts.

After the reaction, the monomeric diisocyanate remaining in the reaction mixture is removed by means of a suitable separation method down to the residual content described.

A preferred separation method is a distillative method, especially thin-film distillation or short-path distillation, preferably with application of reduced pressure.

Particular preference is given to a multistage method in which the monomeric diisocyanate is removed in a short-path evaporator with a jacket temperature in the range from 120 to 200° C. and a pressure of 0.001 to 0.5 mbar.

In the case of IPDI, which is the preferred monomeric diisocyanate, the jacket temperature is preferably in the range from 140 to 180° C.

Preference is given to reacting the monomeric diisocyanate and the polyol and subsequently removing the monomeric diisocyanate remaining in the reaction mixture without use of solvents or entraining agents.

Preference is given to subsequently reusing the monomeric diisocyanate removed after the reaction, i.e., using it again for the preparation of polymer containing isocyanate groups.

In the reaction, the OH groups of the polyol react with the isocyanate groups of the monomeric diisocyanate. This also results in what are called chain extension reactions, in that there is reaction of OH groups and/or isocyanate groups of reaction products between polyol and monomeric diisocyanate. The higher the NCO/OH ratio chosen, the lower the level of chain extension reactions that takes place, and the lower the polydispersity and hence the viscosity of the polymer obtained. A measure of the chain extension reaction is the average molecular weight of the polymer, or the breadth and distribution of the peaks in the GPC analysis. A further measure is the effective NCO content of the polymer freed of monomers relative to the theoretical NCO content calculated from the reaction of every OH group with a monomeric diisocyanate.

The NCO content in a polymer P containing isocyanate groups that has a low monomeric diisocyanate content is preferably at least 80%, especially at least 85%, of the theoretical NCO content which is calculated from the addition of one mole of monomeric diisocyanate per mole of OH groups. Such a polymer has particularly low viscosity and enables moisture-curing polyurethane compositions having particularly good application properties.

A polymer P containing isocyanate groups and having a low monomeric diisocyanate content preferably has a viscosity at 20° C. of not more than 50 Pa·s, especially not more than 40 Pa·s, more preferably not more than Pa·s. The viscosity is determined here with a cone-plate viscometer having a cone diameter 25 mm, cone angle 1°, cone tip-plate distance 0.05 mm, at a shear rate of 10 s⁻¹.

Preferred polymers P containing isocyanate groups enable high-quality, efficiently processible moisture-curing polyurethane compositions having high extensibility and elasticity.

A particularly preferred polymer P containing isocyanate groups and having a low monomeric diisocyanate content has an NCO content in the range from 1% to 2.5% by weight, preferably 1.1% to 2.1% by weight, based on all repeat units in the polyether segment, 80% to 100% by weight, especially 80% to 90% by weight, of 1,2-propyleneoxy groups and 0% to 20% by weight, especially 10% to 20% by weight, of 1,2-ethyleneoxy groups and a monomeric diisocyanate content of not more than 0.3% by weight, and is obtained from the reaction of IPDI with a polyether triol having an average OH functionality in the range from 2.2 to 3, preferably 2.2 to 2.8, especially 2.2 to 2.6, and an OH number in the range from 10 to 42 mg KOH/g, especially 20 to 35 mg KOH/g. Such a polymer together with blocked amines enables moisture-curing polyurethane compositions that are particularly suitable as elastic adhesives or sealants or gap fillers, especially also for electric or electronic applications.

A further particularly preferred polymer P containing isocyanate groups and having a low monomeric diisocyanate content has an NCO content in the range from 2.8% to 7% by weight, based on all repeat units in the polyether segment, 100% propyleneoxy groups and a monomeric diisocyanate content of not more than 0.3% by weight, and is obtained from the reaction of IPDI with at least one polyether diol having an OH number in the range from 44 to 120 mg KOH/g. Such a polymer together with blocked amines enables moisture-curing polyurethane compositions that are particularly suitable as elastic coatings, especially for electric or electronic applications.

In preferred embodiments of the two-component moisture-curable composition according to the present invention, the composition comprises between 1.0 and 2.5% by weight, based on the total two-component composition, of said polymer P containing isocyanate groups or alkoxysilane groups.

Surprisingly it was found that by using polymers P as defined in the claims and further above, such small overall content thereof within the two-component composition still leads to cured, elastomeric products. Normally, traditional polyurethane compositions require at least 10% by weight or more of isocyanate-functional polymers to properly cure.

In some embodiments of the invention, polymer P containing isocyanate groups is subsequently converted to a polymer P containing alkoxysilane groups, by reaction with an organoalkoxysilane that contains an amino group, a hydroxy group, or a mercapto group. The reaction itself is an addition reaction of a hydroxy, amino, or mercapto group to an isocyanate and well known to the skilled person in the field.

The silane groups present in the resulting polymer P containing alkoxysilane groups are preferably alkoxysilane groups of the formula (VII)

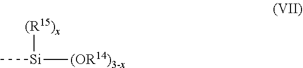

where
R¹⁴ is a linear or branched, monovalent hydrocarbyl radical having 1 to 5 carbon atoms, especially methyl or ethyl or isopropyl;
R¹⁵ is a linear or branched, monovalent hydrocarbyl radical having 1 to 8 carbon atoms, especially methyl or ethyl; and
x is a value of 0 or 1 or 2, preferably 0 or 1, especially 0.

More preferably R¹⁴ is methyl or ethyl.

For particular applications, the R¹⁴ radical is preferably an ethyl group, since, in this case, ecologically and toxicologically harmless ethanol is released in the course of curing of the composition.

Particular preference is given to trimethoxysilane groups, dimethoxymethyl-silane groups or triethoxysilane groups.

In this context, methoxysilane groups have the advantage that they are particularly reactive, and ethoxysilane groups have the advantage that they are toxicologically advantageous and particularly storage-stable.

Suitable aminosilanes for the alkoxysilane-introducing endcapping reaction of an isocyanate-functional polymer P are primary and secondary aminosilanes.

Preference is given to 3-aminopropyltrimethoxysilane, 3-aminopropyldimethoxymethylsilane, 4-aminobutyltrimethoxysilane, 4-amino-3-methylbutyltrimethoxysilane, 4-amino-3,3-dimethylbutyltrimethoxysilane, N-butyl-3-aminopropyltrimethoxysilane, N-phenyl-3-aminopropyltrimethoxysilane, adducts formed from primary amino-silanes such as 3-aminopropyltrimethoxysilane, 3-aminopropyldimethoxy-methylsilane or N-(2-aminoethyl)-3-aminopropyltrimethoxysilane and Michael acceptors such as acrylonitrile, (meth)acrylic esters, (meth)acrylamides, maleic or fumaric diesters, citraconic diesters or itaconic diesters, especially dimethyl or diethyl N-(3-trimethoxysilylpropyl)aminosuccinate. Likewise suitable are analogs of the aminosilanes mentioned with ethoxy or isopropoxy groups in place of the methoxy groups bonded to the silicon atom.

Suitable hydroxysilanes for the alkoxysilane-introducing endcapping reaction of an isocyanate-functional polymer P are especially obtainable from the addition of aminosilanes onto lactones or onto cyclic carbonates or onto lactides. Aminosilanes suitable for the purpose are especially 3-aminopropyltrimeth-oxysilane, 3-aminopropyltriethoxysilane, 4-aminobutyltrimethoxysilane, 4-aminobutyltriethoxysilane, 4-amino-3-methylbutyltrimethoxysilane, 4-amino-3-methylbutyltriethoxysilane, 4-amino-3,3-dimethylbutyltrimethoxysilane, 4-amino-3,3-dimethylbutyltriethoxysilane, 2-aminoethyltrimethoxysilane or 2-aminoethyltriethoxysilane. Particular preference is given to 3-aminopropyl-trimethoxysilane, 3-aminopropyltriethoxysilane, 4-amino-3,3-dimethylbutyl-trimethoxysilane or 4-amino-3,3-dimethylbutyltriethoxysilane.

Suitable lactones are especially γ-valerolactone, γ-octalactone, δ-decalactone, and ε-decalactone, especially γ-valerolactone.

Suitable cyclic carbonates are especially 4,5-dimethyl-1,3-dioxolan-2-one, 4,4-dimethyl-1,3-dioxolan-2-one, 4-ethyl-1,3-dioxolan-2-one, 4-methyl-1,3-dioxolan-2-one or 4-(phenoxymethyl)-1,3-dioxolan-2-one.

Suitable lactides are especially 1,4-dioxane-2,5-dione (lactide formed from 2-hydroxyacetic acid, also called “glycolide”), 3,6-dimethyl-1,4-dioxane-2,5-dione (lactide formed from lactic acid, also called “lactide”) and 3,6-diphenyl-1,4-dioxane-2,5-dione (lactide formed from mandelic acid).

Preferred hydroxysilanes which are obtained in this way are N-(3-triethoxysilylpropyl)-2-hydroxypropanamide, N-(3-trimethoxysilylpropyl)-2-hydroxypropanamide, N-(3-triethoxysilylpropyl)-4-hydroxypentanamide, N-(3-triethoxysilylpropyl)-4-hydroxyoctanamide, N-(3-triethoxysilylpropyl)-5-hydroxydecanamide and N-(3-triethoxysilylpropyl)-2-hydroxypropyl carbamate.

In addition, suitable hydroxysilanes are also obtainable from the addition of aminosilanes onto epoxides or from the addition of amines onto epoxysilanes. Preferred hydroxysilanes which are obtained in this way are 2-morpholino-4(5)-(2-trimethoxysilylethyl)cyclohexan-1-ol, 2-morpholino-4(5)-(2-triethoxysilyl-ethyl)cyclohexan-1-ol or 1-morpholino-3-(3-(triethoxysilyl)propoxy)propan-2-ol.

Suitable mercaptosilanes for the alkoxysilane-introducing endcapping reaction of an isocyanate-functional polymer P are especially 3-mercaptopropyltrimethoxysilane, 3-mercaptopropyldimethoxymethylsilane, and 3-mercaptopropyltriethoxysilane.

Embodiments of the invention using polymers P containing alkoxysilane groups preferably include organosilanes in component B of the two-component composition.

Organosilanes have various advantages in these embodiments. For example, they may act as desiccant or drying agent, in particular vinyl trimethoxysilane. Other organosilanes have co-catalytic activity, in particular aminosilanes such as 3-aminopropyl trimethoxysilane, and/or they act as adhesion promotors, such as 3-glycidoxypropyl trimethoxysilane.

Preferred monomeric or oligomeric aminofunctional alkoxysilanes include N-(n-Butyl)-3-aminopropyltrimethoxysilane, 3-aminopropyltrimethoxysilane, 3-aminopropyldimethoxymethyl-silane, N-(2-aminoethyl)-3-aminopropyltrimethoxysilane, N-(2-aminoethyl)-3-aminopropyldimethoxymethylsilane, N-(2-aminoethyl)-N′-[3-(trimethoxysilyl)-propyl]ethylenediamine and oligomers obtained from the condensation of the mentioned aminosilanes, optionally oligomerized together with alkylalkoxysilanes, in particular methyltrimethoxysilane, ethyltrimethoxysilane, propyltrimethoxysilane, vinyltrimethoxysilane, n-butyltrimethoxysilane, isobutyltrimethoxysilane, phenyltrimethoxysilane, and octyltrimethoxysilane.

Preferred organosilanes acting as desiccants or drying agents are in particular tetraethoxysilane, vinyltrimethoxysilane, vinyltriethoxysilane, propyltrimethoxysilane, or organoalkoxysilanes having a functional group in the α-position to the silane group, especially N-(methyldimethoxysilylmethyl)-O-methylcarbamate, (methacryloyloxymethyl)silanes, and methoxymethylsilanes.

Preferably, in embodiments wherein said polymer P contains alkoxysilane groups, the composition furthermore contains an aminosilane in component B and/or an organic compound containing a tertiary amino group, an amidine group, or a guandine group in either one of components A or B.

The composition according to the present invention comprises in second component B optionally additives selected from dried fillers, pigments, stabilizers, and plasticizers. These additives are generally suitable to be added to polymer P without affecting its storage stability.

The same or other additives may also be added to component A, but in both components it should be avoided to add additives that can react in unwanted ways with the present substances.

These additives are not necessary for the invention to work, but they can give additional advantages or meet specific additional demands.

In principle, it is possible to use a component B consisting of pure polymer P. Such a component B naturally has excellent storage stability, since no added additive can react with reactive polymer P, e.g. by water contained therein. On the other hand, a component B consisting of pure polymer P will have to be mixed into component A in a high volumetric ratio of component A to component B, which needs to be aligned to the respective mixing an application equipment.

Hence, it can be advantageous or in cases even necessary to add additives that increase the total volume of component B or that change the rheological properties of component B.

Care has to be taken that none of the added additives react with polymer P in an undesired way. Fillers, etc. should therefore be dried when added to component B to ensure a sufficient storage stability.

The composition may in one or both components A and B comprise further constituents, especially the following auxiliaries and additives:
additional desiccants or drying agents, especially orthoformic esters, calcium oxide or molecular sieves;
additional plasticizers;
solvents;
further inorganic or organic fillers, especially aluminium oxide (Al₂O₃), boron nitride (BN), aluminium nitride (AlN), magnesium oxide (MgO), zinc oxide (ZnO), chalk, baryte (heavy spar), talcs, quartz flours, quartz sand, dolomites, wollastonites, kaolins, calcined kaolins, mica (potassium aluminum silicate), molecular sieves, silicas including finely divided silicas from pyrolysis processes, industrially produced carbon blacks, metal powders such as iron or steel, PVC powder or hollow spheres;
fibers, especially glass fibers, carbon fibers, metal fibers, ceramic fibers or polymer fibers such as polyamide fibers or polyethylene fibers;
dyes;
pigments, especially titanium dioxide or iron oxides;
rheology modifiers, in particular thickeners or thixotropy additives, especially sheet silicates such as bentonites, derivatives of castor oil, hydrogenated castor oil, polyamides, polyurethanes, urea compounds, fumed (pyrogenic) silicas, cellulose ethers or hydrophobically modified polyoxyethylenes;
stabilizers against oxidation, heat, light or UV radiation;
natural resins, fats or oils such as rosin, shellac, linseed oil, castor oil or soya oil;
non-reactive polymers that are preferably solid at room temperature such as, in particular, homo- or copolymers of unsaturated monomers, especially from the group comprising ethylene, propylene, butylene, isobutylene, isoprene, vinyl acetate or alkyl (meth)acrylates, especially polyethylenes (PE), polypropylenes (PP), polyisobutylenes, ethylene-vinyl acetate copolymers (EVA) or atactic poly-α-olefins (APAO);
further flame-retardant substances, especially the already mentioned filler aluminum hydroxide, magnesium hydroxide, or, in particular, the already mentioned organic phosphoric esters such as, in particular, triethyl phosphate, tricresyl phosphate, triphenyl phosphate, diphenyl cresyl phosphate, isodecyl diphenyl phosphate, tris(1,3-dichloro-2-propyl) phosphate, tris(2-chloroethyl) phosphate, tris(2-ethylhexyl) phosphate, tris(chloroisopropyl) phosphate, tris(chloropropyl) phosphate, isopropylated triphenyl phosphate, mono-, bis- or tris(isopropylphenyl) phosphates of different degrees of isopropylation, resorcinol bis(diphenyl phosphate), bisphenol A bis(diphenyl phosphate) or ammonium polyphosphates;
surface-active substances, especially leveling agents, deaerating agents or defoamers;
biocides, especially algicides, fungicides or substances that inhibit fungal growth;
   and other substances customarily used in polyurethane compositions. It may be advisable to chemically or physically dry certain constituents before mixing them into the composition.

The two-component moisture-curable composition can furthermore comprise a dispersion additive, although the composition can be formulated without such additives. Dispersion additives are well known, e.g., in the field of coating formulations containing fillers and pigments. They are also known as dispersing agents or dispersants or wetting agents and facilitate the compounding of solids into a liquid matrix. A suitable dispersion additive is in particular an ammonium salt or alkyl ammonium salt of a polymer or copolymer containing carboxylate and/or phosphate groups, preferably a polyether and/or polyester polymer containing carboxylate and/or phosphate groups, such as, for example, Byk-W 996, Byk-W 969, Byk-W 985 (available from Altana) and Disparlon DA-234, DA-325, and DA-375 (available from King Industries).

However, preferred embodiments of the two-component composition according to the invention do not contain added dispersing agents or dispersants. Compositions according to the invention without any dispersion additives still can be used as thermally conductive gap fillers, as it is possible to include high amounts, e.g., >70 parts by volume of filler F therein while the viscosity remains sufficiently low for the compositions to be free-flowing liquids. This is especially the case for multimodal fillers, such as multimodal aluminium hydroxide having a hydrophobic coating.

Particularly when using trialkyl and/or triaryl phosphates as plasticizer PL, in particular tris-(2-ethylhexyl)-phosphate, high loadings of fillers can be achieved without any dispersing agents. When these plasticizers PL are used to disperse a filler F that comprises or consists of a multimodal aluminium hydroxide having a hydrophobic coating, it is possible to disperse especially high amounts of filler F in plasticizer PL without using dispersing agents, e.g., at least 75% by volume, based on the mixture of filler and plasticizer.

In preferred embodiments of the two-component moisture-curable composition according to the invention, the composition does not contain polydiorganosiloxanes.

The composition is preferably produced and stored with exclusion of moisture, in particular component B. Typically, it is storage-stable with exclusion of moisture in a suitable package or arrangement, such as, more particularly, a bottle, a canister, a pouch, a bucket, a vat or a cartridge.

In the present document, “two-component” refers to a composition in which the constituents of the composition are present in two different components which are stored in separate containers. Only shortly before or during the application of the composition are the two components mixed with one another, whereupon the mixed composition cures by crosslinking reactions of polymer P and water, either from moisture, in particular air humidity or, if present, water in component A.

Component A is therefore mixed with component B immediately prior to or on application, especially by means of a static mixer or by means of a dynamic mixer.

It is possible to use automatic application equipment, such as manually operated application guns with static or dynamic mixing chambers, or fully automated equipment such as industrial robots equipped with mixing chambers and application nozzles.

The mixing ratio of component A to component B is within a volume ratio of component A to component B of between 1:1 and 200:1. This means that a standard application unit for boostered polyurethane compositions can be used, which typically has a volume ratio of polyurethane adhesive to booster (water-containing paste) of about 50:1.

Advantages of a two-component formulation compared to a one-component formulation in general include a generally higher storage stability, no requirement to dry the fillers F of the component A, and, in case of water being included in component A, a faster, more homogeneous deep-curing behavior due to immediately present water within the mixture after mixing (no need for humidity to diffuse into the mixture).

In preferred embodiments of the two-component moisture-curable composition the volume ratio of component A to component B is between 1:1 and 75:1, in particular between 10:1 and 70:1, more preferably between 25:1 and 65:1, even more preferably between 40:1 and 60:1.

In order to ensure proper mixing of both components, in particular when using static or simple mixing equipment, addition of pigments, dyes, or colorants to either one or both of components A and B can help monitoring the mixing result. Also, fluorescent optical markers can be used if visible coloration of the composition is not desired. However, the two components according to the present invention normally mix well and homogeneously on standard mixing equipment.

The curable composition according to the present invention is preferably applied at ambient temperature, such as room temperature, preferably within a temperature range between 10° C. and 45° C., especially 15° C. to 35° C., and cures under these conditions.

On application, the crosslinking reaction of the isocyanate groups commences, with amino groups created from hydrolysis of some of the isocyanate groups under the influence of moisture. As a result of these reactions, the composition ultimately cures. The catalysts described further above accelerate this curing mechanism catalytically.

If external water is required for the curing, especially in the case of compositions without water added to component A, this can either come from the air (air humidity), or else the composition can be contacted with a water-containing component, for example by painting, for example with a smoothing agent, or by spraying, or water or a water-containing component can be added to the composition on application, for example in the form of a water-containing or water-releasing liquid or paste. A paste is especially suitable if the composition itself is in the form of a paste.

In the case of curing by means of air humidity, the composition cures from the outside inward, at first forming a skin on the surface of the composition. What is called the “skin time” or “skin formation time” is a measure of the curing rate of the composition. The speed of curing is generally determined by various factors, for example the availability of water (e.g., relative air humidity), temperature, etc.

The composition is in principle suitable for a multitude of uses, for example a molding, elastomer, film or membrane, as a potting compound, sealant, gap filler, adhesive, covering, or coating for construction and industrial applications, for example as a seam seal, cavity seal, electrical insulation compound, assembly adhesive, bodywork adhesive, seal, or gap filler. The composition is particularly suitable as an adhesive, gap filler, and/or sealant, especially in automotive manufacturing and e-mobility, for batteries, electronic elements, engine control units, anti-lock breaking and electronic stability control and safety systems, DC/DC converter of hybrid electric vehicles, advanced driver-assistance systems, sensors, or control units. It is also suitable for manufacturing of electric or electronic parts and can be used in all applications, where high heat conductivity and in flame-retardant properties are required.

For an application as gap filler or sealant, the composition preferably has a liquid consistency with low-viscous properties. Such a free-flowing sealant or gap filler is especially applied to a substrate from standard cartridges which are operated manually, by means of compressed air or with a battery, or from a vat or hobbock by means of a delivery pump or an extruder, optionally by means of an application robot.

On application, the composition is preferably applied to at least one substrate. Suitable substrates are especially
glass, glass ceramic, concrete, mortar, brick, tile, gypsum and natural rocks such as limestone, granite or marble;
metals and alloys such as aluminum, iron, steel and nonferrous metals, and also surface-finished metals and alloys such as galvanized or chromed metals or surface coated metals, such as Kynar®- or Duranar®-coated aluminum;
leather, textiles, paper, wood, woodbase materials bonded with resins, for example phenolic, melamine or epoxy resins, resin-textile composites and further polymer composites;
plastics such as polyvinyl chloride (rigid and flexible PVC), acrylonitrile-butadiene-styrene copolymers (ABS), polycarbonate (PC), polyamide (PA), polyesters, poly(methyl methacrylate) (PMMA), epoxy resins, polyurethanes (PUR), polyoxymethylene (POM), polyethyleneterephtalate (PET) polyolefins (PO), polyethylene (PE) or polypropylene (PP), ethylene/propylene copolymers (EPM) and ethylene/propylene/diene terpolymers (EPDM), and also fiber-reinforced plastics such as carbon fiber-reinforced plastics (CFP), glass fiber-reinforced plastics (GFP) and sheet molding compounds (SMC), where the plastics may have been surface-treated by means of plasma, corona or flames;
coated substrates such as powder-coated metals or alloys;
electrocoated (e-coat) surfaces coated by electrophoretic painting processes;
paints or varnishes, especially automotive topcoats.

If required, the substrates can be pretreated prior to the application of the composition, especially by chemical and/or physical cleaning methods or by the application of an adhesion promoter, an adhesion promoter solution or a primer.

In general, it is not required to pre-treat the surfaces prior to application of the composition. The composition shows in preferred embodiments sufficient adhesion, but can be easily removed by pulling, which makes it ideal for application in re-cyclable electronic equipment.

The compositions disclosed herein possess excellent thermal conductivity, in particular of 2.5 W/mK, in preferred embodiments of 3 W/mK, according to ASTM D5470. The compositions disclosed herein generally possess low viscosities of less than 100 Pa·s, preferably less than 75 Pa·s at 23° C. and a shear rate of 10 s⁻¹.

Furthermore, the compositions disclosed herein have the advantage excellent flame retardant properties.

Another aspect of the present invention is a method for improving the thermal dissipation properties of an electric or electronic device or part, wherein a two-component moisture-curable composition according to the present invention and described above including all embodiments is mixed and injected into a gap within said device or part to fill partially or fully said gap and subsequently cures by influence of moisture.

In preferred embodiments of said method, the mixing and/or injecting of said two-component moisture-curable composition is done automatically.

Another aspect of the present invention is the use of an adhesive composition as described herein as a thermally conductive gap filler.

In preferred embodiments of said use, at least one of these substrates is a battery or an electric or electronic device or electronic element.

The use of the composition gives rise to an article that was partially filled with the composition. The article is especially an industrially manufactured good or a consumable good, especially a domestic appliance or a mode of transport such as, more particularly, an automobile, a bus, a truck, a rail vehicle, a ship, an aircraft, a drone, or a helicopter; or the article may be an installable component thereof.

### EXAMPLES

Adduced hereinafter are working examples which are intended to elucidate the invention described in detail. It will be appreciated that the invention is not restricted to these described working examples.

The term “standard climatic conditions” refers to a temperature of 23±1° C. and a relative air humidity of 50±5%.

### Test Methods for Exemplary Compositions:

Viscosity was determined on a MCR 302 rheometer (Anton Paar) according to ISO 3219. Measurement parameters were: Rotation 0.1-10 s⁻¹, measurement point at 10 s⁻¹, temperature 20° C., gap 1.0 mm.

Thermal conductivity was determined according to ASTM D5470-12 on samples cured during 7 days under standard climatic conditions. For the measurements, a TIM (thermal interface material) testing device (Zentrum für Wärmemanagement, Stuttgart, Germany) using the stationary cylinder method was used. Sample dimensions were: Diameter 30 mm, thicknesses 2 mm and 6 mm. The pressure parameters of the measurements were 1, 2, 3, 5, 7, 10 bar.

Shore A hardness was determined to DIN 53505 on test specimens cured under standard climatic conditions for 7 days.

### Compounds Used:

TABLE 1
Compounds used for the example compositions.

| Name | Description, trade name | Density | |
|---|---|---|---|
| IPDI-Polymer | Isocyanate-functional polyurethane | 1.05 | g/cm³ |
| (polymer P) | polymer based on IPDI (synthesis below) | | |
| MDI-Polymer 1 | Isocyanate-functional polyurethane | 1.05 | g/cm³ |
| (polymer P) | polymer based on MDI (synthesis below) | | |
| MDI-Polymer 2 | Isocyanate-functional polyurethane | 1.05 | g/cm³ |
| (polymer P) | polymer based on MDI (synthesis below) | | |
| MDI-Polymer 3 | Isocyanate-functional polyurethane | 1.04 | g/cm³ |
| (reference) | polymer based on MDI (synthesis below). | | |
| | Not according to invention. | | |
| STP-Polymer 1 | Silane-functional polyurethane polymer | 1.05 | g/cm³ |
| (polymer P) | based on MDI-Polymer 2 (synthesis | | |
| | below) | | |
| STP-Polymer 2 | Silane-functional polyurethane polymer | 1.03 | g/cm³ |
| (reference) | based on MDI-Polymer 3 (synthesis | | |
| | below). Not according to invention. | | |
| STP-Polymer 3 | Silane-functional polyether-based polymer | 1.002 | g/cm³ |
| (reference) | (Geniosil ® STP-E30, Wacker Chemie AG) | | |
| Martinal TM-3810 | Multimodal (particle size of coarse fraction | 2.40 | g/cm³ |
| (filler F) | ca. 120 μm and of fine fraction ca. 2 μm), | | |
| | hydrophobically surface-coated aluminium | | |
| | hydroxide (Al(OH)₃) (MARTINAL ® TM- | | |
| | 3810, Huber Martinswerk); undried | | |
| TOF (plasticizer | Tris-(2-Ethylhexyl)-phosphate (Disflamoll ® | 0.92 | g/cm³ |
| PL) | TOF, Lanxess) | | |
| Curing catalyst | Dioctyltin dineodecanoate (TIB KAT ® 223, | 0.998 | g/cm³ |
| | TIB Chemicals) | | |
| Water | Deionized water | 0.997 | g/cm³ |

### Synthesis of Polymers P Containing Isocyanate Groups:

Viscosity was measured with a thermostated Rheotec RC30 cone-plate viscometer (cone diameter 50 mm, cone angle 1°, cone tip-plate distance 0.05 mm, shear rate 10 s⁻¹).

Monomeric diisocyanate content was determined by means of HPLC (detection via photodiode array; 0.04 M sodium acetate/acetonitrile as mobile phase) after prior derivation by means of N-propyl-4-nitrobenzylamine.

### IPDI-Polymer (Polymer P)

780.0 g of Desmophen® 5031 BT (glycerol-started ethylene oxide-terminated polyoxypropylene triol, OH number 28.0 mg KOH/g, OH functionality about 2.3; from Covestro) and 220 g of 1-isocyanato-3,3,5-trimethyl-5-isocyanatomethylcyclohexane (Vestanat® IPDI, from Evonik) were converted in the presence of 0.01 g of dibutyltin dilaurate by a known method at 80° C. to a polyetherurethane polymer having an NCO content of 6.4% by weight, a viscosity of 4.1 Pa·s at 20° C. and a monomeric IPDI content of about 12% by weight.

Subsequently, the volatile constituents, especially the majority of the monomeric IPDI, were removed by distillation in a short-path evaporator (jacket temperature 160° C., pressure 0.1 to 0.005 mbar). The polyetherurethane polymer thus obtained had an NCO content of 1.9% by weight, a viscosity of 8.2 Pa·s at 20° C. and a monomeric IPDI content of 0.02% by weight.

### MDI-Polymer 1 (Polymer P)

725.0 g of Desmophen® 5031 BT (glycerol-started ethylene oxide-terminated polyoxypropylene triol, OH number 28.0 mg KOH/g, OH functionality about 2.3; from Covestro) and 275 g of diphenylmethane 4,4′-diisocyanate (Desmodur® 44 MC L, from Covestro) were converted by a known method at 80° C. to a polyetherurethane polymer having an NCO content of 7.6% by weight, a viscosity of 6.5 Pa·s at 20° C. and a monomeric diphenylmethane 4,4′-diisocyanate content of about 20% by weight.

Subsequently, the volatile constituents, especially a majority of the monomeric diphenylmethane 4,4′-diisocyanate, were removed by distillation in a short-path evaporator (jacket temperature 180° C., pressure 0.1 to 0.005 mbar, condensation temperature 47° C.). The polyetherurethane polymer thus obtained had an NCO content of 1.7% by weight, a viscosity of 19 Pa·s at 20° C. and a monomeric diphenylmethane 4,4′-diisocyanate content of 0.04% by weight.

### MDI-Polymer 2 (Polymer P)

727.0 g of polyoxypropylene diol (OH number 28 mg KOH/g, Acclaim® 4200, from Covestro) and 273.0 g of diphenylmethane 4,4′-diisocyanate (Desmodur 44 MC L, from Covestro) were converted by a known method at 80° C. to a polymer having an NCO content of 7.4% by weight, a viscosity of 5.2 Pa·s at 20° C. and a monomeric diphenylmethane 4,4′-diisocyanate content of about 17% by weight.

Subsequently, the volatile constituents, especially a majority of the monomeric diphenylmethane 4,4′-diisocyanate, were removed by distillation in a short-path evaporator (jacket temperature 180° C., pressure 0.1 to 0.005 mbar, condensation temperature 47° C.). The linear polymer thus obtained had an NCO content of 1.8% by weight, a viscosity of 13.3 Pa·s at 20° C. and a monomeric diphenylmethane 4,4′-diisocyanate content of 0.08% by weight.

MDI-Polymer 3 (not According to Invention, Prepared with NCO/OH=2.1/1)

400 g polyoxypropylene diol (Acclaim® 4200, from Covestro AG; OH number 28.5 mg KOH/g) and 52 g 4,4′-diphenylmethane diisocyanate (Desmodur 44 MC L, from Covestro AG) were reacted at 80° C. according to the known procedure to yield an NCO-terminated polymer with an isocyanate group content of 1.85 wt %, which was liquid at room temperature.

### Synthesis of Polymers P Containing Alkoxysilane Groups:

Silane-functional polymers were prepared by endcapping of the obtained NCO-functional polymers with an amino-functional alkoxysilane using a known method.

As silane endcapper, diethyl N-(3-trimethoxysilylpropyl)aminosuccinate (351.5 g/mol) was used, which was synthesized from the reaction of 3-aminopropyltrimethoxysilane and diethyl maleate in a molar ratio of about 1/1.

### STP-Polymer 1 (Polymer P)

To an initial charge of MDI-Polymer 2 prepared as described above, was added under a nitrogen atmosphere with exclusion of moisture a slight molar excess of 1.1 equivalents (of NH groups of the silane endcapper relative to NCO groups of the polymer) of the above described silane endcapper and the mixture was stirred at 60° C. until isocyanate groups were no longer detectable by FT-IR spectroscopy. The resulting polymer was cooled to room temperature and stored with exclusion of moisture.

### STP-Polymer 2 (Reference)

STP-Polymer 2 was prepared by the same procedure as STP-Polymer 1, with the difference that in this synthesis MDI-Polymer 3 was reacted with the silane endcapper until isocyanate groups were no longer detectable by FT-IR spectroscopy. The resulting polymer was cooled to room temperature and stored with exclusion of moisture.

STP-Polymer 3 (reference) is a commercial product and was used as obtained.

### Example Two—Component Compositions

A series of example two-component compositions C1 and C2 according to the invention was prepared by mixing the ingredients of each respective component A and B shown in Table 2 in the indicated sequence as listed in the table under nitrogen atmosphere in a vacuum mixer until homogeneous pastes were obtained. The individual components A and B were filled into internally coated aluminum spreading piston cartridges that were closed airtight and stored under standard climate conditions for at least 24 h until the testing protocol was employed. For testing of the cured compositions, the respective components A and B of the compositions were mixed in a volume ratio of A:B=50:1 and subsequently left for curing during 7 days under standard climate. Viscosity was measured before curing on freshly mixed compositions. The properties and test results of these 50:1 mixtures are shown in Table 3.

TABLE 2
Example compositions C1 and C2 with respective components
A and B (all numbers in wt.-%, based on the total
individual composition A or B, respectively).

| Composition (components A) | C1-A | C2-A |
|---|---|---|
| Martinal TM-3810 (filler F) | 89.75 | 90.1 |
| TOF (plasticizer PL) | 9.9 | 9.9 |
| Water | 0.25 | — |
| Curing Catalyst | 0.1 | — |
| Composition (components B) | C1-B | C2-B |
| IPDI-Polymer (polymer P) | 100 | — |
| MDI-Polymer 1 (polymer P) | — | 100 |

“n/m” means not measured.

Table 3 shows that the compositions C1 and C2 according to the invention are highly suitable as injectable gap fillers with outstanding thermal conductivity properties. Surprisingly, their viscosity is comparably low despite the extremely high filler loading, and although they contain extremely low amounts of polymer P, they properly cure into cross-linked elastomeric products. Inclusion of water and curing catalyst is not mandatory to ensure proper curing of the compositions, but it significantly decreases the curing time without affecting the intended properties. Equally surprising is the fact that these compositions can be formulated without special additives such as dispersion agents and do not require drying of the filler to prevent storage stability issues.

TABLE 3
Properties and test results of the investigated examples C1 and C2.

| Properties and test results of mixed compositions | C1-A + | C2-A + |
|---|---|---|
| A + B (50:1 volume mixture) | C1-B | C2-B |
| Content of polymer P (in mixture) [parts per volume] | 2.0 | 2.4 |
| Content of filler F (in mixture) [parts per volume] | 75.6 | 75.8 |
| Content of plasticizer PL (in mixture) | 21.7 | 21.8 |
| [parts per volume] | | |
| Content of curing catalyst (in mixture) | 0.2 | — |
| [parts per volume] | | |
| Content of water (in mixture) [parts per volume] | 0.5 | — |
| Viscosity of mixture (shear rate 10 s⁻¹), 23° C. [Pa · s] | 70 | n/m |
| Viscosity of mixture (shear rate 10 s⁻¹), 60° C. [Pa · s] | 50 | n/m |
| Rheologically suitable for injection application | yes | yes |
| Curing time | <24 h | <15 min |
| Shore A hardness after curing | 11 | n/m |
| Thermal conductivity after curing (W/mK) | 3.1 | 3.2 |

“n/m” means not measured.

Comparative Tests with Compositions of the State of the Art:

A series of additional compositions C3 to C7, including compositions according to the invention and reference compositions according to the state of the art was prepared using the same preparation and curing procedure as in the above-described compositions C1 and C2. The mixing ratio of components A and B in this series was different than for compositions C1 and C2 and is shown in Table 5. The composition details of the compositions C3 to C7 are shown in Table 4.

TABLE 4
Example compositions C3 to C7 with respective
components A and B (all numbers in wt.-%, based on the
total individual composition A or B, respectively).

| Composition (components A) | C3-A * | C4-A | C5-A * | C6-A * | C7-A |
|---|---|---|---|---|---|
| Martinal TM-3810 (filler F) | 92 | 92 | 92 | 92.1 | 92.1 |
| TOF (plasticizer PL) | 7.9 | 7.9 | 7.9 | 7.9 | 7.9 |
| Curing Catalyst | 0.1 | 0.1 | 0.1 | — | — |
| Composition (components B) | C3-B * | C4-B | C5-B * | C6-B * | C7-B |
| MDI-Polymer 2 (polymer P) | — | — | — | — | 100 |
| MDI-Polymer 3 (reference) | — | — | — | 100 | — |
| STP-Polymer 1 (polymer P) | — | 100 | — | — | — |
| STP-Polymer 2 (reference) | 100 | — | — | — | — |
| STP-Polymer 3 (reference) | — | — | 100 | — | — |

“n/m” means not measured.
* not according to invention (reference example).

### Test Protocol:

Thermal conductivity of compositions C3 to C7 was measured with the same method as used for compositions C1 and C2 and described further above. The press-in force was measured with a tensiometer (Zwick). The test composition was placed on a metal surface. An aluminum piston with a diameter of about 40 mm diameter was placed on top and the material was compressed to an initial position of 5 mm. The material was then compressed from 5 mm to 0.3 mm with a velocity of about 1 mm/s and the force deflection curve was recorded. The force (N) at 0.5 mm thickness was then recorded in the data table and determined as the press-in force. A material having a low viscosity normally has a press-in force of 700 N or less. A high viscosity material normally has a press-in force greater than 700 N, or about 800 N or more. A material having a low viscosity, and which is suitable as gap filler preferably has a press-in force of about 600 N or less, even more preferably about 500 N or less, and most preferably about 400 N or less.

The results of this test protocol are shown in Table 5.

TABLE 5
Properties and test results of the investigated examples C3 to C7.

| Properties and test results of mixed | | | | | |
|---|---|---|---|---|---|
| compositions A + B | C3 * | C4 | C5 * | C6 * | C7 |
| Gravimetric mixing ratio (A:B) | 96:4 | 96:4 | 96:4 | 96:4 | 96:4 |
| Thermal conductivity after curing (W/mK) | 2.50 | 2.50 | 2.51 | 2.52 | 2.50 |
| Press-in force [N] | 558 | 420 | 663 | 545 | 442 |

* not according to invention (reference example).

Table 5 shows that compositions containing polymers P according to the invention exhibit a significantly lower press-in force, yet the same thermal conductivity properties, than comparable compositions of the state of the art that contain polymers not produced according to the invention but are otherwise identical. This surprising difference is visible with both isocyanate- and alkoxysilane-functional polymer-based compositions. The surprisingly lower press-in force of compositions according to the invention leads to a better injectability of the compositions than the state of the art, while the thermal conductivity properties are maintained.

1. A two-component moisture-curable composition, comprising
in a first component A
between 50 and 99 parts per volume, based on the total two-component composition, of at least one filler F;
between 10 and 30 parts by volume, based on the total two-component composition, of at least one plasticizer PL;
optionally between 0.1 and 2 parts per volume, based on the total two-component composition, of water; and
in a second component B
between 0.5 and 50 parts per volume, based on the total two-component composition, of at least one polymer P containing isocyanate groups or alkoxysilane groups;
optionally additives selected from dried fillers, pigments, stabilizers, organosilanes, and plasticizers;
and optionally up to 1 part per volume, based on the total two-component composition, of at least one catalyst for the curing of isocyanate-functional polymers or alkoxysilane-functional polymers in either one or both of component A and component B;
wherein the volume ratio of component A to component B is between 1:1 and 200:1 and components A and B are stored in separated containers and mixed before or during application of the moisture-curable composition;
wherein
the filler F is selected from the list consisting of aluminium oxide, aluminium hydroxide, boron nitride, aluminium nitride, magnesium oxide, magnesium hydroxide, zinc oxide, and any mixture of these fillers; and
the polymer P containing isocyanate groups or alkoxysilane groups is obtained from the reaction of at least one monomeric diisocyanate with at least one polyether polyol in an NCO/OH ratio of at least 3/1, and subsequent removal of a majority of the residual monomeric diisocyanates by means of a suitable separation method, and optionally subsequent endcapping of the isocyanate groups on the obtained isocyanate-functional polymer by reaction with an organoalkoxysilane that contains an amino group, a hydroxy group, or a mercapto group.

2. The two-component moisture-curable composition as claimed in claim 1, wherein the composition comprises between 1.0 and 2.5% by weight, based on the total two-component composition, of the polymer P containing isocyanate groups or alkoxysilane groups.

3. The two-component moisture-curable composition as claimed in claim 1, wherein the filler F comprises or consists of aluminium hydroxide and optionally aluminium oxide, optionally furthermore comprising boron nitride and/or magnesium oxide.

4. The two-component moisture-curable composition as claimed in claim 1, wherein the filler F comprises or consists of a multimodal aluminium hydroxide having a hydrophobic coating.

5. The two-component moisture-curable composition as claimed in claim 1, wherein the polyether polyol is a polyether triol having an average OH functionality in the range from 2.2 to 3, and an OH number in the range from 10 to 42 mg KOH/g.

6. The two-component moisture-curable composition as claimed in claim 1, wherein the diisocyanate is diphenylmethane 4,4′-diisocyanate or 1-isocyanato-3,3,5-trimethyl-5-isocyanatomethylcyclohexane.

7. The two-component moisture-curable composition as claimed in claim 1, wherein the plasticizer PL comprises or consists of a trialkyl and/or triaryl phosphate.

8. The two-component moisture-curable composition as claimed in claim 1, wherein the composition comprises between 75.0 and 95.0% by weight, based on the total two-component composition, of the filler F.

9. The two-component moisture-curable composition as claimed in claim 1, wherein the composition comprises between 7.5 and 15.0% by weight, based on the total two-component composition, of the plasticizer PL.

10. The two-component moisture-curable composition as claimed in claim 1, wherein the volume ratio of component A to component B is between 25:1 and 75:1.

11. The two-component moisture-curable composition as claimed in claim 1, wherein the composition does not contain added dispersing agents or dispersants.

12. The two-component moisture-curable composition as claimed in claim 1, wherein the polymer P contains alkoxysilane groups and the composition furthermore contains an aminosilane in component B and/or an organic compound containing a tertiary amino group, an amidine group, or a guandine group in either one of components A or B.

13. Method for improving the thermal dissipation properties of an electric or electronic device or part, wherein a two-component moisture-curable composition according to claim 1 is mixed and injected into a gap within the device or part to fill partially or fully the gap and subsequently cures by influence of moisture.

14. A method comprising applying the two-component moisture-curable composition according to claim 1 as a thermally conductive gap filler.

15. The method of claim 13, wherein the gap that is filled is part of a battery or of an electric or electronic device.
